(19) United States
(12) Patent Application Publication
(10) Pub. No.: US 2011/0001150 A1
(43) Pub. Date: Jan. 6, 2011

(54) LIGHT EMITTING DIODE AND METHOD FOR FABRICATING THEREOF

(76) Inventor: William Yu, Laytonsville, MD (US)

Correspondence Address: DOWELL & DOWELL P.C., 103 Oronoco St., Suite 220, Alexandria, VA, 22314, US

(21) Appl. No.: 12/452,514

(22) PCT Filed: Jul. 7, 2008
(86) PCT No.: PCT/CN2008/001276

§ 371 Date: Apr. 2, 2010

(30) Foreign Application Priority Data
Jul. 9, 2007 (CN) 200710043599.7

(51) Int. Cl. H01L 33/52; H01L 33/62

(52) U.S. Cl. 257/98; 438/26; 438/29; 257/99; 257/E33.059; 257/E33.066; 257/E33.061

(57) ABSTRACT

The present invention provides a light-emitting diode (LED) and a method for manufacturing said LED. The LED is characterized that, the silica gel as the interlayer is provided between the transparent organic material and the chip. The method for manufacturing is characterized that, a gel applying step for applying the silica gel and the solidifying step for solidifying the semi-finished product of LED applied with the silica gel are included prior to the material packaging step for packaging using the transparent organic material. The LED of this invention and the LED manufactured by the method of this invention have no light decay for the low-power, such as Ø5 mm or less LED, and little light decay for the high-power LED, and have the advantages of excellent weathering resistance and low production cost.

### FIELD OF THE INVENTION

The present invention relates to a light-emitting diode (LED) and the manufacturing method of said LED.

### BACKGROUND

In the prior technology, the LED, especially the low-power LED, such as a LED with Ø5 mm diameter after package or Ø3 mm diameter after package, is composed of a support, a light emissive chip on the support, and epoxy resin as a transparent organic material for enveloping the chip and the support, or constructed by applying an epoxy resin layer including the phosphor material on a chip, then enveloping the epoxy resin layer, chip and the support using epoxy resin. Such LED packaging technology is developed, and optical layout of the thereby obtained LED is simple and flexible. However, there is a problem of large light decay.

It is pointed out by some prior arts that the main reason of light decay caused by the packaging technology lies in that the short-wavelength light beam with the wavelength shorter than 450 nm is easy to be absorbed by the epoxy resin materials, of which the absorptivity is up to 45%. Thus, it is considered that, the luminescence spectrum of the white light LED includes the short wavelength light beam with the wavelength shorter than 450 nm, and the conventional epoxy resin sealing materials can easily be destroyed by this short-wavelength light beam. The large quantity of light of the high power white light LED accelerates this deterioration of the sealing material. The damage and deterioration decrease the transmissivity of the light beam of the LED to this epoxy resin material, therefore result in the light decay.

Now refer to FIG. 4, this figure shows the light decay in the conventional Ø5 mm packaged LED, wherein the light decay of the visible white light is the severest. After being used for 3500 hours, its light output is 65% of the original output, and after being used for 6000 hours, the light output even decays to be 50% or less of the original output.

Other transparent organic materials, the polymethyl methacrylate (PMMA) or polycarbonate (anti-ultraviolet radiation PC), have more excellent weathering resistance compared with the epoxy resin. However, their melting point is low. When packaged on the chip as packaging materials, some portions of them, which contact with the chip are easily melting due to the large energy density of the light output from the chip, and therefore these materials are not fit for the packaging material of the LED.

In order to avoid the deterioration of the epoxy resin, it is brought forward that the epoxy resin should be ceased as the packaging material in the LED and shall be substituted by the silica gel. However, the silica gel package decreases the simplicity and flexibility of the structure of the conventional LED packaging technology, and increases the manufacturing cost due to its high price.

### SUMMARY OF THE INVENTION

To solve the above problems, the object of the present invention is to provide a LED with the low light decay and the excellent weathering resistance, and the method for manufacturing said LED.

A LED according to the present invention, includes a support and a chip on the support, a silica gel on the chip, and a transparent organic material for enveloping the silica gel.

A method for manufacturing a LED according to the present invention, includes: a chip fixing step for adhering a chip on a support using an adhesive; an electrically connecting step for connecting the support to the chip using a conductive wire to realize an electrical connection; a gel applying step for applying silica gel on the chip; a solidifying step for solidifying a semi-finished product of the LED applied with the silica gel; a material packaging step for packaging in the peripheral area of the silica gel with the transparent organic material; and a post-solidifying step for solidifying the LED packaged with the transparent organic material.

The inventor further discovers that, such deteriorations of the epoxy resin in the LED starts on the surface area of the epoxy resin which contacts with the luminescent chip, resulting in the decrease of the transmissivity of the light beam to said epoxy resin material. The deterioration degree increases as the power of the short-wavelength light absorbed by per unit area of the contact area of the epoxy resin material increases. Especially for the conventional Ø5 mm, Ø3 mm packaged LED packaging technology, the above deterioration also occurs in the process in which the blue photoluminescence phosphor powder emits the white light. In the conventional packaging technology for the Ø5 mm, Ø3 mm white light LED, an epoxy resin layer including phosphor powder is applied on a chip, and the deterioration of the epoxy resin layer causes the decrease of the transmissivity of the blue light of the photoluminescence phosphor powder, and the decrease the excited white light accordingly. Such dual deterioration results in severe light decay in the conventional white light LED. According to this discovery, the applicant provides a method to decrease the light energy density per unit area of the light-receiving surface of the epoxy resin in LED, and block the direct contact between the epoxy resin and the excited luminescence outer layer of the phosphor powder particles, therefore slow down the deterioration of the epoxy resin, instead of simply ceasing the usage of the epoxy resin packaging.

According to the LED and its manufacture method in the present invention, the silica gel as an interlayer is provided between the transparent organic material and the chip, that is, after used to envelope a chip, the silica gel is further enveloped by the transparent organic material as a casing. Since the absorptivity for the light beam with the wavelength shorter than 450 nm of the silica gel is lower than 1%, the light decay due to the deterioration will not occur on the surface of the silica gel contacting with the chip, even the energy density (i.e. the optical power passing through per unit area) of the light beam with the wavelength shorter than 450 nm passing through the surface of the silica gel contacting with the chip is large. On the other hand, since the silica gel is provided as an interlayer between the transparent organic material acting as the casing and the chip, which enlarges the contact area between the transparent organic material and the silica gel. The energy density when the light beam with the wavelength shorter than 450 nm emitted by the chip reaches the contact surface between the transparent organic material and the silica gel after passing through the silica gel, can decrease extremely through enlarging this contact area. Thereby, when the transparent organic material is epoxy resin, the light decay due to the deterioration on the contact surface between the epoxy resin and the silica gel changes to be slow, and the life time of the LED is prolonged; when the transparent organic material is polymethyl methacrylate or polycarbonate, the light energy density on the contact surface between the polymethyl methacrylate or polycarbonate and silica gel decreases extremely, the packaged polymethyl methacrylate or polycarbonate will not melt, and a reliable package can be obtained. So, the LED packaged using the polymethyl methacrylate or polycarbonate may possess excellent weathering resistance. Since the silica gel as the interlayer is employed, the LED according to the present invention overcomes the light decay problem existing in the conventional LED, and meanwhile reserves the conventional LED packaging technology employing the epoxy resin envelope. Furthermore, since the chip is enveloped by a mass of the transparent organic material after enveloped by a small quantity of silica gel, the production cost of the LED according to the present invention decreases as compared with the LED packaged by silica gel entirely.

### BRIEF DESCRIPTION OF THE DRAWINGS

FIG. 1 is the stereogram showing the basic structure of the LED according to an embodiment of the present invention.

FIG. 2 is the cross-sectional view showing the basic structure of the LED according to another embodiment of the present invention.

FIG. 3 shows the manufacture flowchart of the LED according to the present invention.

FIG. 4 shows the light decay curve of the conventional Ø5 mm packaged LED.

### DETAILED DESCRIPTION OF THE INVENTION

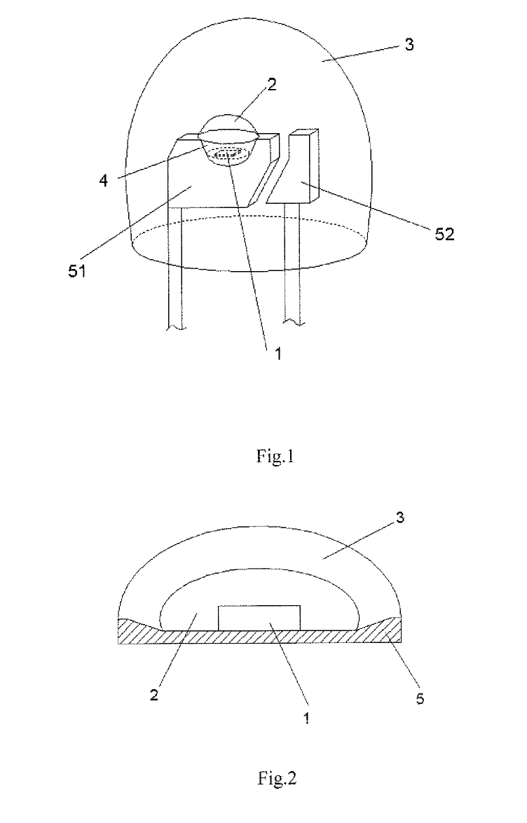

FIG. 1 is the stereogram showing the basic structure of the LED according to an embodiment of the present invention. Its structure is the same as that of the Ø3 mm and Ø5 mm packaged low-power LED, except that a silica gel 2 is applied on a chip 1. In this embodiment, the LED includes conductive supports 51 and 52, a chip 1 provided on the support 51 or 52, and further includes silica gel 2 on the chip 1 and transparent organic material 3 for enveloping the silica gel 2. The transparent organic material 3 may be epoxy resin, polymethyl methacrylate or polycarbonate.

See FIG. 1, in a specific structure example, supports 51 and 52 are composed of a pair of supports, i.e. a left support 51 and a right support 52. The lower portions of the left and right supports 51 and 52 are formed with a pair of electric pins. A bowl 4 is formed on the upper portion of one of the pair of supports, for example, the left support 51. The chip 1 is at the bottom of the bowl 4. In the case where the chip 1 is a double-sided electrodes, the electrode at the bottom of the chip 1 electrically connects directly with the left support 51 through the bottom of the bowl 4, and the electrode on the upper surface of the chip 1 electrically connects with the other support 52 through a conductive wire, for example a gold wire (not shown). In the case where the chip 1 is a single-sided electrode and two electrodes are on the upper surface of the chip 1, the two electrodes of the chip 1 connect the left and right supports 51 and 52 through a conductive wire, for example a gold wire (not shown), respectively. The silica gel 2 is on the chip 1, preferably envelopes the surrounding side wall of the chip 1. The transparent organic material 3 envelopes the silica gel 2, and further can envelope the supports 51 and 52.

In order to convert the blue light emitted by the chip 1 into the white light, phosphor powder can be mixed into the silica gel 2. If to convert the white light into the light in other colors, a pigment layer can be applied on the upper surface of the silica gel 2 mixed with phosphor powder, or a pigment can be mixed in the transparent organic material (not shown), but the light of the former is more uniform than that of the latter. On the other hand, in order to convert the blue light into the white light, a phosphor powder film (not shown) can be applied on the upper surface of the chip 1, or on the upper surface of the silica gel 2 (not mixed with phosphor powder). The phosphor powder film applied on the upper surface of the chip 1 is composed of the silica gel and the phosphor powder, and the phosphor powder film applied on the upper surface of the silica gel 2 is composed of the silica gel and the phosphor powder, or the transparent organic material and the phosphor powder. If to convert the white light into the light in other colors, a pigment layer (not shown) can be applied on the upper surface of the phosphor powder film, or a pigment layer (not shown) can be applied on the upper surface of the silica gel which is not applied with the phosphor powder, or pigments can be mixed in the transparent organic material, however, the colored light emitted by the LED applied with the pigment layer is more uniform as compared with the one with the transparent organic material mixed with the pigment. The “upper surface” in the present applicant indicates the surface whose normal points to the light output direction of the LED.

As a variation, a platform on which the chip 1 is provided can be formed on the upper portion of the left support 51, instead of forming the bowl 4, or the chip 1 can be directly provided on the upper portion of one of the supports 51 and 52 without the platform, that is, we only need to put chip 1 on the support 51 or 52. The silica gel 2 may not envelope the surrounding sidewall of the chip 1, ands we only need to put it on the chip 1.

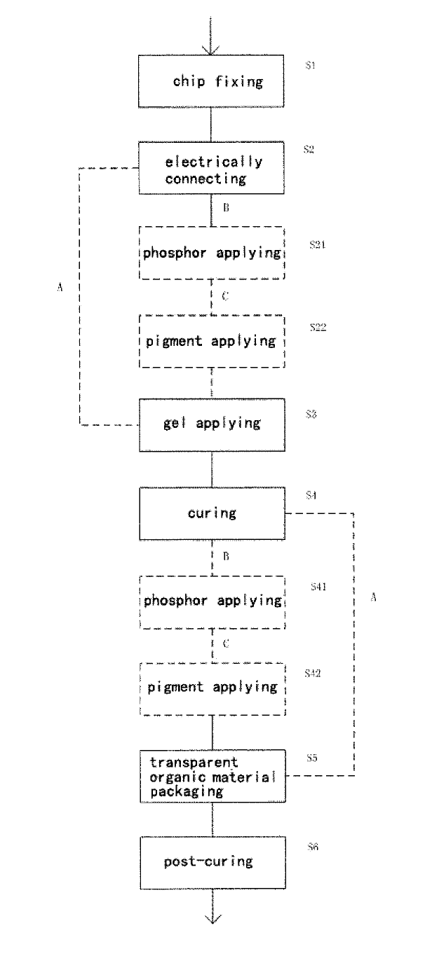

Now refer to FIG. 2, which shows the LED structure of another embodiment of the present invention. It is a basic structure of the high power LED, wherein, the electric pin is not shown by the figure. This LED structure includes a base plate 5 acting as a support, a chip 1 on the base plate 5, a silica gel 2 on the chip 1 and a transparent organic material 3 for enveloping the silica gel 2. This structure is the same as the conventional LED structure, except that the transparent organic material 3 is added on the upper surface of the silica gel 2. The configuration of the phosphor powder, phosphor powder film, pigment and pigment layer, and the composition of the phosphor powder film is as same as those in the first embodiment.

As a variation, another type of LED provided by the present invention may include a plurality of chips. Each chip is provided on respective support. The silica gels are applied on the respective chips. The respective silica gels share one transparent organic material enveloping (casing). The configuration of the phosphor powder, phosphor powder film, pigment and a pigment layer and the composition of the phosphor powder film are the same as those in the above embodiment. In this example, each chip can be provided on a common support, herein each chip can be applied with respective silica gels, or can share a silica gel (layer), but one transparent organic material envelope is shared.

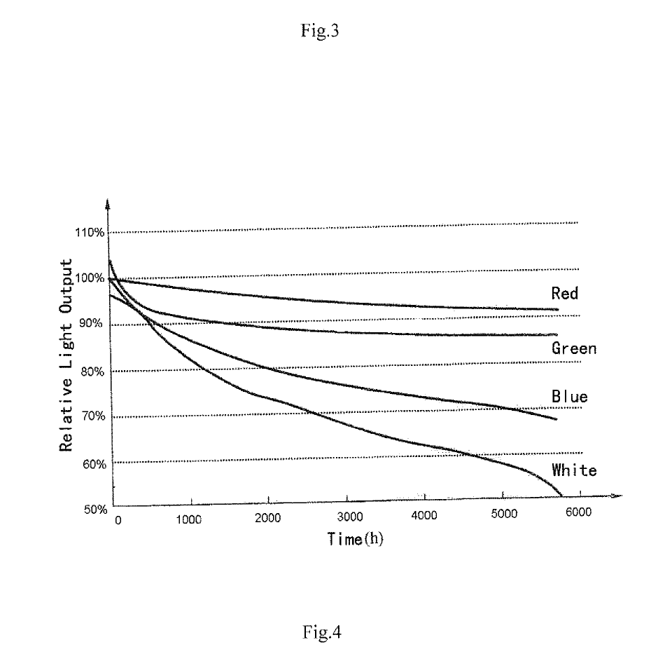

The manufacture method of the LED according to the present invention is described with reference to FIG. 3. The method has three types, including Method A, B, C respectively.

Method A is a basic one, which is adapted for the natural color LED applied with the silica gel and white LED applied with the silica gel mixed with the phosphor powder. Method A includes step S1, S2, S3, S4, S5 and S6 as shown in FIG. 3. At the chip fixing step S1, the chip 1 is adhered to the support 51 or 5 by the adhesive, that is, for the LED described in the first embodiment, the chip 1 is adhered to the bottom portion of the bowl 4 on the upper portion of the left support 51, on the other hand, for the structure described in the second embodiment, the chip 1 is adhered to the upper surface of the base plate 5. Entering into the electrically connecting step S2, the supports 51 and 52 and the chip 1 are connected together by a conductive wire or the support 5 and chip 1 are connected together by a conductive wire, for example a gold wire, to realize the electrical connection. In the case where the chip 1 in the first embodiment is a double-sided electrode, the electrical connection between one electrode of chip 1 and the left support 51 is realized while the chip 1 is adhered to the bottom of the bowl 4 by the conductive adhesive at S1, thereby at S2, the electric connection can be realized by connecting another electrode of the chip 1 on the upper surface of with the right support 52 by a conductive wire such as a gold wire; in the case where the chip 1 in the first embodiment is a single-sided electrode, the two electrodes should be connected to the left and right supports 51 and 52 by conductive wires such as gold wires respectively. Entering into the gel applying step S3, the chip 1 in the bowl 4 or the base plate 5 is applied with the silica gel, and the silica gel 2 is formed in the bowl 4 or base plate 5 (as can be seen from FIG. 2, the circumference of the base plate 5 has ridged surrounding walls), the silica gel 2 can protrude to be higher than the bowl 4 or the surrounding walls of the base plate 5 (see FIG. 1 and FIG. 2). In order to make the LED emit the white light, the phosphor powder can be mixed in the silica gel prior to applying the silica gel, wherein, e.g. the SLM75441A/B gel produced by the Watt corporation (Germany) can be used as the silica gel, and the 00902/4-3-2/80911 phosphor powder produced by HongDa corporation (Taiwan) can be used as the phosphor powder. Entering into the solidifying step S4, the solidifying is performed for the semi-finished product of the LED applied with the silica gel 2, and generally can be performed in the baking oven. The solidifying temperature is at 125±5□, and the solidifying time is 85-95 minutes. The solidifying temperature and solidifying time herein is set in accordance with the characteristic of the silica gel and phosphor powder of the above products, and they vary in accordance with the varieties or types of the silica gel and phosphor powder. Entering into the material packaging step S5, the semi-finished product of the LED is packaged at the peripheral of the silica gel 2 by the transparent organic material 3, in FIG. 1, the transparent organic material 3 also package the supports 51 and 52; and in FIG. 2, the transparent organic material 3 is packaged in the bottom plate 5 and protrudes over the surrounding walls. At step S5, in the case where the transparent organic material is the epoxy resin, said “packaging” employs a perfusion technology; in the case where the organic material is the polymethyl methacrylate or polycarbonate, said “packaging” employs a plastic injection molding technology. After entering into the post-solidifying step S6, the post-solidifying process is performed for the LED packaged with the transparent organic material, and the finished product of the LED is formed. In Method A, if the LED in other color is desired, the pigment may be mixed in the transparent organic material prior to packaging the transparent organic material 3.

Method B is adapted for the white light LED applied with the phosphor powder film. Where the phosphor powder are not mixed in the silica gel and the white light is desired to emitted from the LED, the phosphor powder film should be added in the LED which emit the blue light. The differences between the method A and B are that, the phosphor powder applying step S21 for applying phosphor powder on the upper surface of the chip 1 is added between the step S2 and S3 of Method A, or the phosphor powder applying step S41 for applying the phosphor powder film on the upper surface of the silica gel 2 is added between the step S4 and S5 of Method A, wherein, the phosphor powder applied on the upper surface of the chip 1 is formed by mixing the silica gel and phosphor powder, and the phosphor powder film applied on the upper surface of the silica gel 2 can be formed by mixing the silica gel and phosphor powder, or mixing the transparent organic material and phosphor powder. In Method B, if the LED in other color is desired, a pigment may be mixed in the transparent organic material prior to packaging the transparent organic material 3.

Method C is adapted for obtaining the LED in other color through adding the pigment layer in the white light LED. The differences between Method C and B are that, the step S22 or step S42 for applying the pigment layer on the upper surface of the phosphor powder film, or the step for applying the pigment layer on the upper surface of the silica gel 2 without a phosphor film applied (not shown) is added between the step S21 and S3 of Method B. The advantage of the LED in which the pigment layer is used to convert the luminous color is that, the luminous color of said LED is more uniform as compared with the one with the epoxy resin mixed with the pigment.

In the above manufacture method, due to the phosphor powder film applied on the upper surface of the chip 1 is formed by mixing the silica gel and phosphor powder, the direct contact between the transparent organic material 3 and the chip 1 is avoided, furthermore the silica gel 2 is put between the transparent organic material 3 and the chip 1, which decreases the light energy density per unit area of the light receiving surface of the transparent organic material 3, therefore the light decay is dually slowed down.

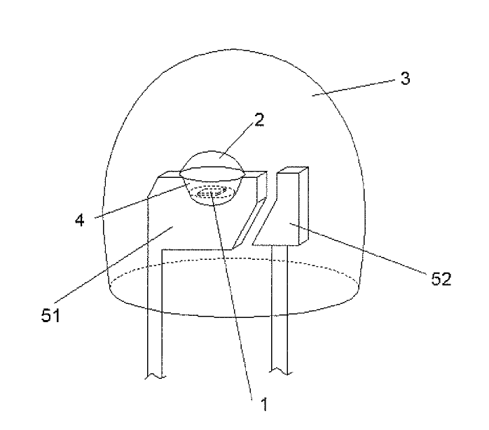

The technical effect of the preset invention is described with reference to the Table 1 and FIG. 4 below.

TABLE 1

| date | | voltage | Illuminance |
|---|---|---|---|
| (month/day/year) | time | (V) | (Lux) |
| 12/20/2006 | 9:00 | 120.2 | 212 |
| | PM | | |
| 12/21/2006 | 11:40 | 121.0 | 216 |
| | PM | | |
| 12/23/2006 | 2:00 | 121.6 | 220 |
| | AM | | |
| 12/24/2006 | 1:30 | 122.1 | 220 |
| | AM | | |
| 12/25/2006 | 9:20 | 119.0 | 208 |
| | PM | | |
| 12/27/2006 | 2:40 | 120.6 | 214 |
| | AM | | |
| 12/28/2006 | 9:20 | 118.5 | 205 |
| | PM | | |
| 12/29/2006 | 1:00 | 121.2 | 214 |
| | AM | | |
| 12/30/2006 | 2:15 | 120.7 | 212 |
| | AM | | |
| 12/31/2006 | 4:26 | 121.5 | 214 |
| | AM | | |
| 01/01/2007 | 11:25 | 121.5 | 214 |
| | PM | | |
| 01/02/2007 | 3:45 | 121.9 | 216 |
| | AM | | |
| 01/02/2007 | 11:05 | 120.2 | 211 |
| | PM | | |
| 01/04/2007 | 12:05 | 122.0 | 215 |
| | AM | | |
| 01/06/2007 | 2:51 | 123.1 | 219 |
| | AM | | |
| 01/06/2007 | 9:36 | 121.0 | 210 |
| | PM | | |
| 01/07/2007 | 9:55 | 121.4 | 212 |
| | PM | | |
| 01/09/2007 | 1:08 | 122.0 | 215 |
| | AM | | |
| 01/10/2007 | 10:56 | 119.8 | 207 |
| | PM | | |
| 01/11/2007 | 9:45 | 121.6 | 211 |
| | PM | | |
| 01/12/2007 | 9:30 | 121.8 | 212 |
| | PM | | |
| 01/14/2007 | 1:49 | 121.9 | 213 |
| | AM | | |
| 01/16/2007 | 10:12 | 121.4 | 211 |
| | PM | | |
| 01/17/2007 | 11:59 | 121.6 | 210 |
| | PM | | |
| 01/19/2007 | 11:35 | 119.8 | 208 |
| | PM | | |
| 01/21/2007 | 12:20 | 120.9 | 209 |
| | AM | | |
| 01/22/2007 | 1:02 | 120.6 | 211 |
| | AM | | |
| 01/26/2007 | 2:00 | 119.8 | 211 |
| | AM | | |
| 01/27/2007 | 11:59 | 121.3 | 214 |
| | PM | | |
| 01/29/2007 | 12:24 | 120.4 | 211 |
| | AM | | |
| 02/03/2007 | 1:45 | 120.8 | 224 |
| | AM | | |
| 02/06/2007 | 11:11 | 120.6 | 222 |
| | PM | | |
| 02/07/2007 | 12:57 | 120.8 | 224 |
| | AM | | |
| 03/24/2007 | 10:26 | 121.1 | 228 |
| | PM | | |
| 03/25/2007 | 6:20 | 119.6 | 226 |
| | AM | | |
| 05/15/2007 | 8:10 | 119.9 | 212 |
| | PM | | |

For the purpose of comparing with the conventional technology as shown in FIG. 4, a Ø5 mm packaged white light LED sample is manufactured according to Method A of the present invention, and is tested under a settled condition, forming the Table 1. As shown in Table 1, the testing time is from Dec. 19, 2006 to May 15, 2007. The 120V commercial power is applied to the sample LED. The working current of the LED is 20 mA. The LED has worked continuously for 148 days, i.e. about 3552 hours. There is no distinct light decay as seen from the Table 1. Comparatively, as shown by the white light curve in FIG. 4, in the same working period, the light output from the conventional Ø5 mm packaged white light LED decays to 65% of the original output of the LED when being electrified. Furthermore, the test is still performing until this application is filed, and there is no distinct light decay in the LED of the present invention. As compared with the curve shown in FIG. 4, it can be seen that, as the time passes, more predominance of the present invention represents.

Although the present invention has been described in detail in conjunction with the above embodiments, the details described in the embodiments should not be considered to limit the present invention. The present invention should be determined by the soul defined by the claims appended.

1. A LED, including a support and a chip on the support, characterized in that, it further includes:
a silica gel on the chip; and
a transparent organic material for enveloping the silica gel.

2. The LED as described in claim 1, characterized in that, phosphor powder is mixed in the silica gel.

3. The LED as described in claim 2, characterized in that, a pigment layer is provided between the transparent organic material and the silica get.

4. The LED as described in claim 1, characterized in that, it further includes a phosphor powder film located between the chip and the silica gel, or between the silica gel and the transparent organic material.

5. The LED as described in claim 4, characterized in that, a pigment layer is provided on an upper surface of the phosphor powder film, or on an upper surface of silica gel on which the phosphor powder film is not applied.

6. The LED as described in claim 1, characterized in that, the transparent organic material is an epoxy resin, polymethyl methacrylate or polycarbonate.

7. The LED as described in claim 6, characterized in that, the support is a pair of supports, and the chip is on one of the pair of supports.

8. The LED as described in claim 1, characterized in that, the chip is a plurality of chips.

9. The LED as described in claim 8, characterized in that, the transparent organic material is an epoxy resin, polymethyl methacryate or polycarbonate.

10. A method for manufacturing a LED, including:
a) a chip fixing step for adhering a chip on a support using an adhesive;
b) an electrically connecting step for connecting the support to the chip using a conductive wire to realize an electrical connection;
c) a gel applying step for applying silica gel on the chip;
d) a solidifying step for solidifying a semi-finished product of the LED applied with the silica gel;
e) a material packaging step for packaging at the peripheral of the silica gel using a transparent organic material; and
f) a post-solidifying step for solidifying the LED packaged with the transparent organic material.

11. The method for manufacturing as described in claim 10, characterized in that, the transparent organic material is an epoxy resin, polymethyl methacryate or polycarbonate.

12. The method for manufacturing a LED as described in claim 11, characterized in that, in the case where the transparent organic material is the epoxy resin, the packaging in step e) is a perfusion technology; in the case where the transparent organic material is the polymethyl methacrylate or polycarbonate, the packaging in the step e) is a plastic injection molding technology.

13. The method for manufacturing a LED as described in claim 12, characterized in that, phosphor powder is mixed in the silica gel.

14. The method for manufacturing described in claim 13, characterized in that, it further includes a pigment applying step for applying a pigment layer on the upper surface of the silica gel between step d) and step e).

15. The method for manufacturing a LED as described in claim 12, characterized in that, it further includes, a phosphor powder film applying step for applying a phosphor powder film on the upper surface of the chip between step b) and step c), or on the upper surface of the silica gel between step d) and step e), wherein, the phosphor powder film applied on the upper surface of the chip is composed of silica gel and phosphor powder, and the phosphor powder film applied on the upper surface of the silica gel is composed of silica gel and phosphor powder, or is composed of a transparent organic material and phosphor powder.

16. The method for manufacturing a LED as described in claim 15, characterized in that, it further includes a pigment layer applying step for applying a pigment layer on the upper surface of the phosphor powder, or on the upper surface of the silica gel on which the phosphor powder film is not applied.

17. The method of manufacturing a LED as described in claim 10, characterized in that, in the chip fixing step, the support is a pair of supports, the adhesive is a conductive adhesive, and the chip is adhered to one of the pair of supports; and in the electrically conducting step, a gold wire connects the other one of the pair of supports and the chip.

18. The method of manufacturing a LED as described in claim 17, characterized in that, the material packaging step further includes packaging the pair of supports.
